(19) United States
(12) Patent Application Publication
(10) Pub. No.: US 2025/0280705 A1
(43) Pub. Date: Sep. 4, 2025

(54) WINDOW MANUFACTURING METHOD AND DISPLAY DEVICE

(71) Applicant: Samsung Display Co., LTD., Yongin-si, Gyeonggi-do (KR)

(72) Inventors: GWANGTAEK LEE, Yongin-si, Gyeonggi-do (KR); TAEWOO PARK, Yongin-si, Gyeonggi-do (KR)

(21) Appl. No.: 18/807,507

(22) Filed: Aug. 16, 2024

(30) Foreign Application Priority Data
Oct. 16, 2023 (KR) 10-2023-0137360

(51) Int. Cl. H10K 59/80; H10K 59/12

(52) U.S. Cl. CPC H10K 59/873; H10K 59/1201

(57) ABSTRACT

A display device includes a display panel and a patterned glass disposed on the display panel and including a first non-patterned part, a patterned part, and a second non-patterned part, which are arranged in a first direction. A first groove extending in a second direction crossing the first direction in a plan view, and a second groove extending from the first groove toward a lower surface of the patterned part are defined in an upper surface of the patterned part, and a width of the first groove in the first direction may be smaller than a width of the second groove.

This application claims priority to Korean Patent Application No. 10-2023-0137360, filed on Oct. 16, 2023, and all the benefits accruing therefrom under 35 U.S.C. § 119, the content of which in its entirety is herein incorporated by reference.

### BACKGROUND

### 1. Field

The disclosure herein relates to a window manufacturing method and a display device including a window manufactured thereby.

### 2. Description of the Related Art

An electronic device displays various images on a display screen to provide information to a user. In general, an electronic device displays information within a given screen. Recently, flexible electronic devices including flexible display panels that are foldable are being developed. A flexible electronic device may be folded, rolled, or bent unlike a rigid electronic device. A flexible electronic device having a shape that is variously changeable may be carried regardless of the existing screen size thereof, and thus user convenience is improved.

An electronic device includes a display panel and a window disposed on the display panel to protect the display panel. A plurality of patterns may be defined in the window to ensure flexibility of a flexible electronic device.

### SUMMARY

The disclosure provides a method for manufacturing a window having patterns invisible to a user and having improved surface quality, and a display device including the window.

An embodiment of the inventive concept provides a display device, and the display device may include a display panel and a patterned glass disposed on the display panel and including a first non-patterned part, a patterned part, and a second non-patterned part, which are arranged in a first direction. A first groove extending in a second direction crossing the first direction in a plan view, and a second groove extending from the first groove toward a lower surface of the patterned part may be defined in an upper surface of the patterned part, and a width of the first groove in the first direction may be smaller than a width of the second groove.

In an embodiment of the inventive concept, a window manufacturing method may include forming, on an upper surface of a glass, a plurality of patterns disposed in a first direction and extending in a second direction crossing the first direction by irradiating the glass with a laser beam, sealing the patterns, and filling the patterns with a resin, and the resin may be filled into the patterns through capillarity.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of an embodiment of an electronic device according to the inventive concept;

FIG. 2 illustrates that the electronic device in FIG. 1 is folded;

FIG. 3 is an exploded perspective view of an embodiment of an electronic device according to the inventive concept;

FIG. 4 is a cross-sectional view taken along line I-I′ in FIG. 3;

FIG. 5 is a view illustrating a cross-section of a display panel in FIG. 3;

FIG. 6 is a plan view of the display panel in FIG. 5;

FIG. 7 is an enlarged view of a first region A1 in FIG. 4;

FIG. 8 illustrates a patterned glass in FIG. 7;

FIG. 9 is a cross-sectional view taken along line II-II′ in FIG. 8;

FIG. 10 illustrates a comparative example of a patterned glass;

FIG. 11 is a drawing for describing another embodiment of a patterned glass;

FIGS. 12A to 12E are drawings for describing a method for manufacturing a window illustrated in FIG. 7; and

FIG. 13A and FIG. 13B illustrate a comparative example of a patterned glass.

### DETAILED DESCRIPTION

An advantage and a feature of the inventive concept, and a method of achieving the same will be clarified by referring to embodiments to be described in detail below with reference to the accompanying drawings. However, the inventive concept is not limited to the embodiments to be disclosed below and will be embodied in various forms. These embodiments are provided merely so that the inventive concept is comprehensively disclosed, and so that a scope of the inventive concept is comprehensively conveyed to a person skill in the art, and the inventive concept is only defined within a scope of the appended claims. Like reference numerals or symbols refer to like elements throughout.

An element or layer being referred to as being “on” another element or layer includes not only a case in which the element or layer is directly on the other element or layer but also a case in which an intervening element or layer is disposed therebetween. In contrast, an element being referred to as being “directly on” another element or layer implies that there is no intervening element or layer disposed therebetween. As used herein, the term “and/or” includes any and all combinations of one or more of mentioned items.

Spatially relative terms, such as “below”, “beneath”, “lower”, “above”, “upper”, may be used herein to easily describe one element or feature's relationship to another element or feature as illustrated in the drawings. It will be understood that the spatially relative terms are intended to encompass different orientations of an element in use or operation in addition to an orientation illustrated in the drawings. Like reference numerals or symbols refer to like elements throughout.

Although the terms first, second, etc. may be used herein to describe various elements, components, and/or sections, these elements, components, and/or sections are not limited by these terms. These terms are used to distinguish one element, component, or section from another element, component, or section. Thus, a first element, component, or section mentioned below may be a second element, component, or section without departing from the spirit of the inventive concept.

The embodiments described herein will be described with reference to a plan view and a cross-sectional view, which are ideal schematic views of the inventive concept. Accordingly, a shape of an illustrative drawing may be changed due to a manufacturing technique and/or tolerance. Thus, embodiments of the inventive concept are not limited to a particular form illustrated herein and include a form variation that may occur according to a manufacturing process. Therefore, regions illustrated in a drawing as examples have schematic properties, and shapes of the regions illustrated in the drawing are intended to provide examples of particular forms of a region of an element and are not intended to limit the scope of the inventive concept.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within +30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, an embodiment of the inventive concept will be described in detail with reference to the accompanying drawings.

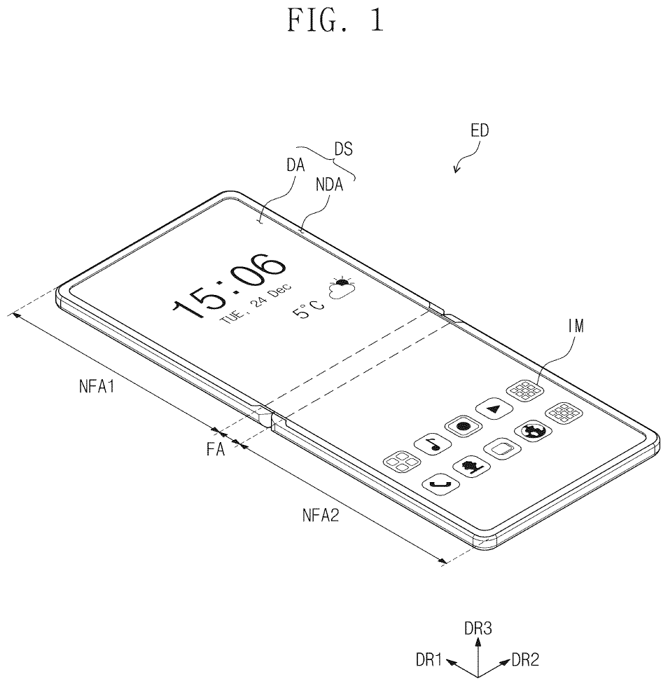

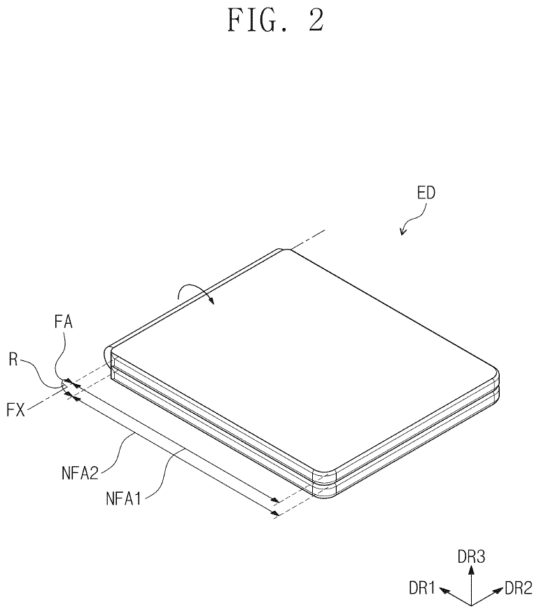

FIG. 1 is a perspective view of an embodiment of an electronic device according to the inventive concept. FIG. 2 illustrates that the electronic device in FIG. 1 is folded.

Referring to FIG. 1, an electronic device ED in an embodiment of the inventive concept may have a quadrangular shape, e.g., a rectangular shape having long sides extending in a first direction DR1 and short sides extending in a second direction DR2 crossing the first direction DR1. However, the inventive concept is not limited thereto, and the electronic device ED may have various shapes such as a circle and a polygon. The electronic device ED may be a flexible electronic device.

Hereinafter, a direction which substantially perpendicularly crosses a plane defined by the first direction DR1 and the second direction DR2 is defined as a third direction DR3. In addition, as used herein, the wording “in a plan view” may be defined as a state of being viewed in the third direction DR3. In addition, as used herein, the term “overlap” may refer to a state in which components are disposed to overlap each other in a plan view.

The electronic device ED may include a folding region FA and a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged in the first direction DR1.

One folding region FA and two non-folding regions NFA1 and NFA2 are illustrated in an embodiment, but the number of the folding region FA and the number of the non-folding regions NFA1 and NFA2 are not limited thereto. In an embodiment, the electronic device ED may include more than two non-folding regions and a plurality of folding regions disposed between the non-folding regions, for example.

An upper surface of the electronic device ED may be defined as a display surface DS and may have a plane defined by the first direction DR1 and the second direction DR2. Images IM generated from the electronic device ED may be provided to a user through the display surface DS.

The display surface DS may include a display region DA and a non-display region NDA around the display region DA. The display region DA may display an image, and the non-display region NDA may not display an image. The non-display region NDA may surround the display region DA and define an edge of the electronic device ED printed in a predetermined color.

Although not illustrated, the electronic device ED may include a plurality of sensors and at least one camera.

Referring to FIG. 2, the electronic device ED may be a foldable electronic device ED capable of folding or unfolding. In an embodiment, the folding region FA may be bent with respect to a folding axis FX parallel to the second direction DR2, and thus the electronic device ED may be folded, for example. The electronic device ED may be folded while having a curvature radius R. The folding axis FX may be defined as a short axis parallel to a short side of the electronic device ED.

When the electronic device ED is folded, the electronic device ED may be in-folded so that the first non-folding region NFA1 and the second non-folding region NFA2 face each other, and the display surface DS is not exposed to the outside. However, the inventive concept is not limited thereto. In an embodiment, the electronic device ED may be out-folded with respect to the folding axis FX so that the display surface DS is exposed to the outside, for example.

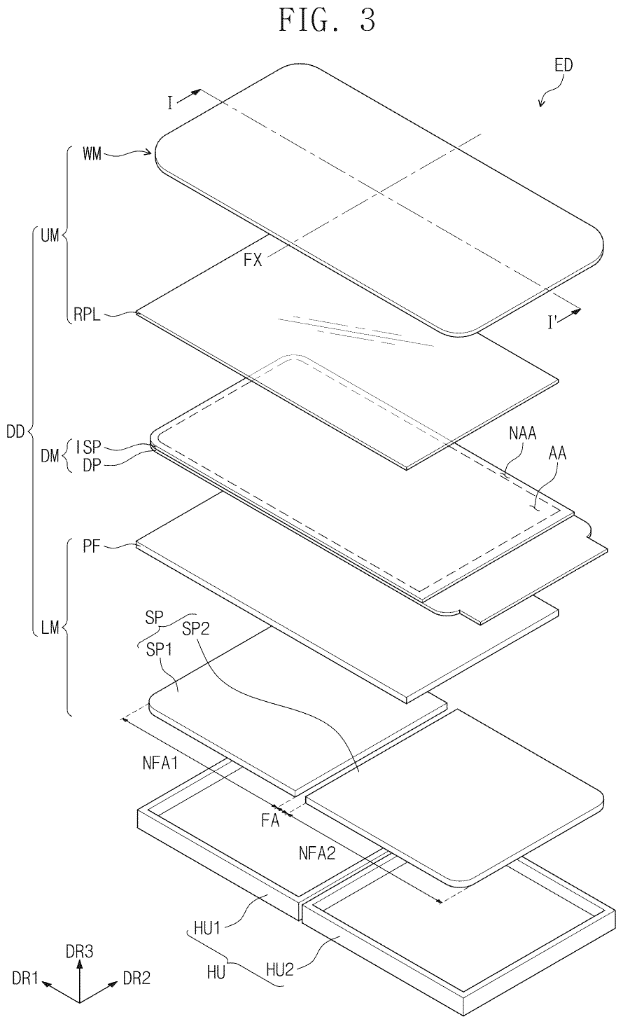

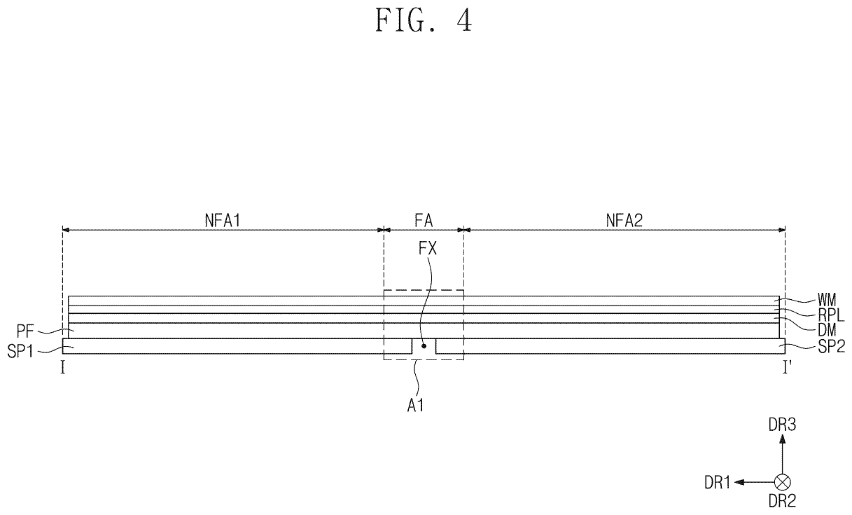

FIG. 3 is an exploded perspective view of an embodiment of an electronic device according to the inventive concept. FIG. 4 is a cross-sectional view taken along line I-I′ in FIG. 3.

Referring to FIG. 3 and FIG. 4, an electronic device ED may include a display device DD and a housing HU. Although not illustrated, the electronic device ED may further include a mechanical structure for controlling a folding operation of the display device DD.

The display device DD in an embodiment of the inventive concept may include a display module DM for displaying an image, an upper module UM disposed on the display module DM, and a lower module LM disposed below the display module DM. The display module DM may constitute a portion of the display device DD, and particularly, the display module DM may generate an image. The display module DM may display an image in response to an electrical signal and transmit/receive information about an external input. An active region AA and a peripheral region NAA may be defined in the display module DM. The active region AA may be defined as a region in which an image provided from the display module DM is emitted.

The peripheral region NAA is adjacent to the active region AA. In an embodiment, the peripheral region NAA may surround the active region AA, for example. However, this is illustrated in an embodiment, and the peripheral region NAA may be defined in various shapes and is not limited to a particular embodiment. In an embodiment, the active region AA of the display module DM may overlap at least a portion of the display region DA in FIG. 1.

The display module DM may include a display panel DP and an input sensing unit ISP. The display panel DP in an embodiment of the inventive concept may be a light-emitting display panel, but an embodiment of the inventive concept is not particularly limited thereto. In an embodiment, the display panel DP may be an organic light-emitting display panel, an inorganic light-emitting display panel, or a quantum dot light-emitting display panel, for example. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, the display panel DP will be described as an organic light-emitting display panel.

The display panel DP may be a flexible display panel. Accordingly, the display panel DP may be entirely rolled or folded or unfolded with respect to a folding axis FX.

The input sensing unit ISP may be directly disposed on the display panel DP. In an embodiment of the inventive concept, the input sensing unit ISP may be formed on the display panel DP through a continuous process. That is, when the input sensing unit ISP is directly disposed on the display panel DP, no adhesive film is disposed between the input sensing unit ISP and the display panel DP. However, the inventive concept is not limited thereto. An adhesive film may be disposed between the input sensing unit ISP and the display panel DP. In this case, the input sensing unit ISP and the display panel DP may not be manufactured through a continuous process, and the input sensing unit ISP may be manufactured through a process separate from that for the display panel DP and then fixed to an upper surface of the display panel DP with an adhesive film.

The display panel DP generates an image, and the input sensing unit ISP acquires coordinate information about a user's input (e.g., a touch event).

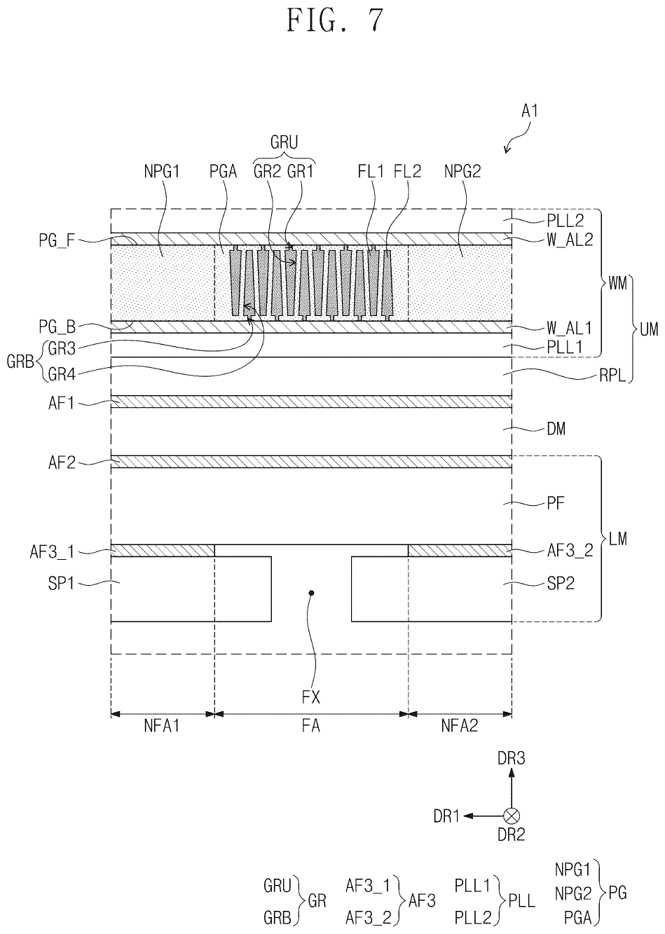

The upper module UM may include a window WM disposed on the display module DM. The window WM may include an optically transparent insulating material. Accordingly, an image generated from the display module DM may be easily perceived by a user through the window WM. The window WM will be described in detail later with reference to FIG. 7.

The upper module UM may further include at least one functional layer disposed between the display module DM and the window WM. In an embodiment of the inventive concept, a functional layer may be an anti-reflective layer RPL for preventing external light reflection.

The anti-reflective layer RPL may prevent elements that constitute the display module DM from being visible from the outside due to external light incident through a front surface of the display device DD. The anti-reflective layer RPL may include a retarder and a polarizer. The retarder may be a film-type retarder or a liquid crystal coating-type retarder and may include a λ/2 retarder and/or a λ/4 retarder. However, the disclosure is not limited thereto, and the retarder may include various other wave phase retarders. The polarizer may also be a film-type polarizer or a liquid crystal coating-type polarizer. The film type may include a stretchable synthetic resin film, and the liquid crystal coating type may include liquid crystals arranged in a predetermined arrangement. The retarder and the polarizer may be implemented as a single polarizing film. The functional layer may further include a protective film disposed above or below the anti-reflective layer RPL.

The lower module LM may include a supporting plate SP disposed on a rear surface of the display module DM to support the display module DM, and a protective film PF disposed between the display module DM and the supporting plate SP. The supporting plate SP may include supporting plate of which the number corresponds to that of non-folding regions NFA1 and NFA2. In an embodiment of the inventive concept, the supporting plate SP may include a first supporting plate SP1 and a second supporting plate SP2 disposed to be spaced apart from the first supporting plate SP1.

The first and second supporting plates SP1 and SP2 may be disposed to respectively correspond to first and second non-folding regions NFA1 and NFA2. The first supporting plate SP1 is disposed to overlap a first non-folding region NFA1 of the display module DM, and the second supporting plate SP2 is disposed to overlap a second non-folding region NFA2 of the display module DM. Each of the first and second supporting plates SP1 and SP2 may include a metal material or a plastic material.

When the display module DM is in an unfolded state as illustrated in FIG. 1, the first and second supporting plates SP1 and SP2 are spaced apart from each other in a first direction DR1. When the display module DM is folded with respect to a folding axis FX as illustrated in FIG. 2, the first and second supporting plates SP1 and SP2 may be spaced apart from each other in a third direction DR3.

The first and second supporting plates SP1 and SP2 may be spaced apart from each other with respect to a folding region FA. The first and second supporting plates SP1 and SP2 may overlap a portion of the folding region FA. That is, a spaced distance between the first and second supporting plates SP1 and SP2 in the first direction DR1 may be smaller than a width of the folding region FA.

Although not illustrated, the supporting plate SP may further include a connecting module for connecting the first and second supporting plates SP1 and SP2. The connecting module may include a hinge module or a multi-joint module.

The supporting plate SP is illustrated as including two supporting plates SP1 and SP2, but the inventive concept is not limited thereto. That is, when a plurality of folding axes FX is provided, the supporting plate SP may include a plurality of supporting plates that are separated from each other with respect to the plurality of folding axes FX. In addition, the supporting plate SP may be provided as one piece without being separated into the first and second supporting plates SP1 and SP2. In this case, a bending portion may be provided to the supporting plate SP to correspond to the folding region FA. An opening defined through the supporting plate SP or a groove recessed from one surface of the supporting plate SP may be provided in the bending portion.

The protective film PF may be disposed between the display module DM and the supporting plate SP. The protective film PF may be disposed below the display module DM to protect a rear surface of the display module DM. The protective film PF may include a synthetic resin film, and may be a polyimide film or a polyethylene terephthalate film, for example. However, this is an illustrative embodiment, and thus the protective film PF is not limited thereto.

The housing HU may be coupled to the display device DD, particularly to the window WM, and accommodate the display module DM and the lower module LM. The housing HU is illustrated as including first and second housings HU1 and HU2 separated from each other, but the inventive concept is not limited thereto. Although not illustrated, the electronic device ED may further include a hinge structure for connecting the first and second housings HU1 and HU2.

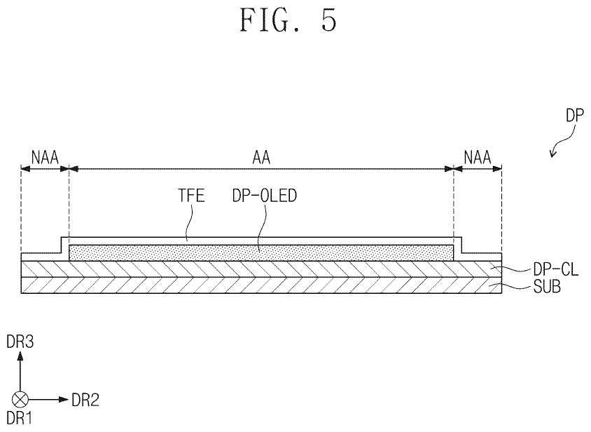

FIG. 5 is a view illustrating a cross-section of a display panel in FIG. 3.

In an embodiment, FIG. 5 illustrates a cross section of the display panel DP viewed in a first direction DR1.

Referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE which covers the display element layer DP-OLED.

The substrate SUB may include an active region AA and a peripheral region NAA around the active region AA. The substrate SUB may include a flexible plastic material such as polyimide (“PI”). The display element layer DP-OLED may be disposed on the active region AA.

A plurality of pixels may be disposed in the active region AA. Each of the pixels may include a light-emitting element connected to a transistor disposed on the circuit element layer DP-CL and disposed on the display element layer DP-OLED.

The thin-film encapsulation layer TFE may be disposed on the circuit element layer DP-CL to cover the display element layer DP-OLED. The thin-film encapsulation layer TFE may include inorganic layers and an organic layer between the inorganic layers. The inorganic layers may protect the pixels from moisture/oxygen. The organic layer may protect pixels PX from foreign substances such as dust particles.

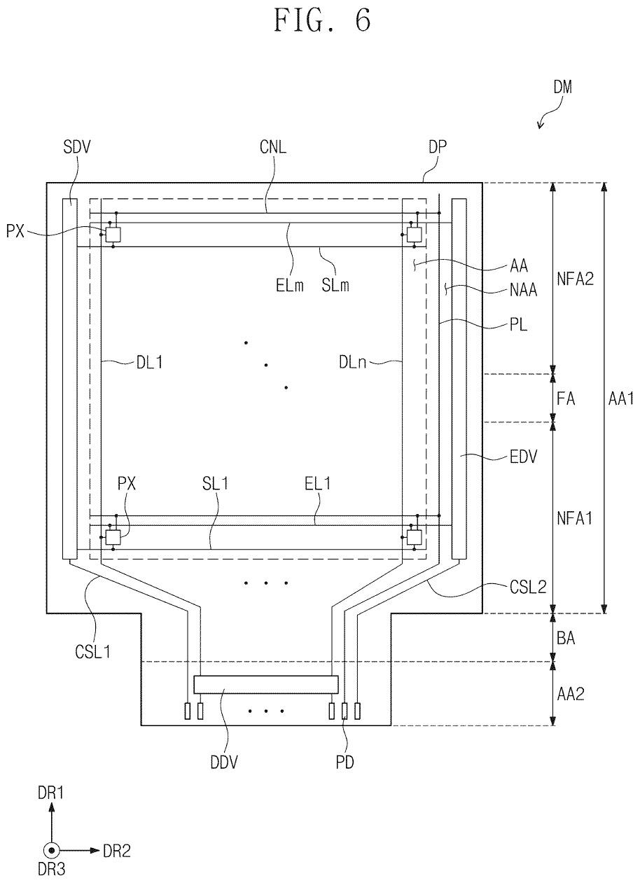

FIG. 6 is a plan view of the display panel in FIG. 5.

Referring to FIG. 6, a display module DM may include the display panel DP, a scan driver SDV, a data driver DDV, and an emission driver EDV.

The display panel DP may include a first region AA1, a second region AA2, and a bending region BA between the first region AA1 and the second region AA2. The bending region BA may extend in a second direction DR2, and the first region AA1, the bending region BA, and the second region AA2 may be arranged in a first direction DR1.

The first region AA1 may include an active region AA and a peripheral region NAA around the active region AA. The peripheral region NAA may surround the active region AA. The active region AA may be a region where an image is displayed, and the peripheral region NAA may be a region where an image is not displayed. The second region AA2 and the bending region BA may be a region where an image is not displayed.

When viewed in the second direction DR2, the first region AA1 may include a first non-folding region NFA1, a second non-folding region NFA2, and a folding region FA between the first non-folding region NFA1 and the second non-folding region NFA2.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a power line PL, a plurality of connecting lines CNL, and a plurality of pads PD. Here, m and n are natural numbers. The pixels PX may be disposed in the active region AA and connected to the scan lines SL1 to SLm, the data lines DL1 to DLn, and the emission lines EL1 to ELm.

The scan driver SDV and the emission driver EDV may be disposed in the peripheral region NAA. The scan driver SDV and the emission driver EDV may be disposed in sections of the peripheral region NAA respectively adjacent to two sides of the first region AA1 opposed to each other in the second direction DR2. The data driver DDV may be disposed in the second region AA2. The data driver DDV may be manufactured in a form of an integrated circuit chip and disposed (e.g., mounted) on the second region AA2.

The scan lines SL1 to SLm may extend in the second direction DR2 and may be connected to the scan driver SDV. The data lines DL1 to DLn may extend in the first direction DR1 and may be connected to the data driver DDV via the bending region BA. The emission lines EL1 to ELm may extend in the second direction DR2 and may be connected to the emission driver EDV.

The power line PL may extend in the first direction DR1 and may be disposed in the peripheral region NAA. The power line PL may be disposed between the active region AA and the emission driver EDV, but the inventive concept is not limited thereto, and thus, the power line PL may be disposed between the active region AA and the scan driver SDV.

The power line PL may extend to the second region AA2 via the bending region BA. In a plan view, the power line PL may extend toward a lower end of the second region AA2. The power line PL may receive a driving voltage.

The connecting lines CNL may extend in the second direction DR2 and may be arranged in the first direction DR1. The connecting lines CNL may be connected to the power line PL and the pixels PX. The driving voltage may be applied to the pixels PX through the power line PL and the connecting lines CNL connected to each other.

The first control line CSL1 may be connected to the scan driver SDV and extend toward the lower end of the second region AA2 via the bending region BA. The second control line CSL2 may be connected to the emission driver EDV and extend toward the lower end of the second region AA2 via the bending region BA. The data driver DDV may be disposed between the first control line CSL1 and the second control line CSL2.

In a plan view, the pads PD may be adjacent to the lower end of the second region AA2. The data driver DDV, the power line PL, the first control line CSL1, and the second control line CSL2 may be connected to the pads PD.

The data lines DL1 to DLn may be connected to corresponding pads PD through the data driver DDV. In an embodiment, the data lines DL1 to DLn may be connected to the data driver DDV, and the data driver DDV may be connected to pads PD respectively corresponding to the data lines DL1 to DLn, for example.

Although not illustrated, a printed circuit board may be connected to the pads PD, and a timing controller and a voltage generator may be disposed on the printed circuit board. The timing controller may be manufactured as an integrated circuit chip and disposed (e.g., mounted) on the printed circuit board. The timing controller and the voltage generator may be connected to the pads PD through the printed circuit board.

The timing controller may control operations of the scan driver SDV, the data driver DDV, and the emission driver EDV. The timing controller may generate a scan control signal, a data control signal, and an emission control signal in response to control signals which are received from the outside. The voltage generator may generate the driving voltage.

The scan control signal may be provided to the scan driver SDV through the first control line CSL1. The emission control signal may be provided to the emission driver EDV through the second control line CSL2. The data control signal may be provided to the data driver DDV. The timing controller may receive image signals from the outside and convert data formats of the image signals to comply with specifications of interface with the data driver DDV and provide the converted image signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate, in response to the data control signal, a plurality of data voltages corresponding to the image signals. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may receive the data voltages in response to the scan signals. The pixels PX may display an image by emitting light having luminance corresponding to the data voltages in response to the emission signals. An emission time of the pixels PX may be controlled by the emission signals.

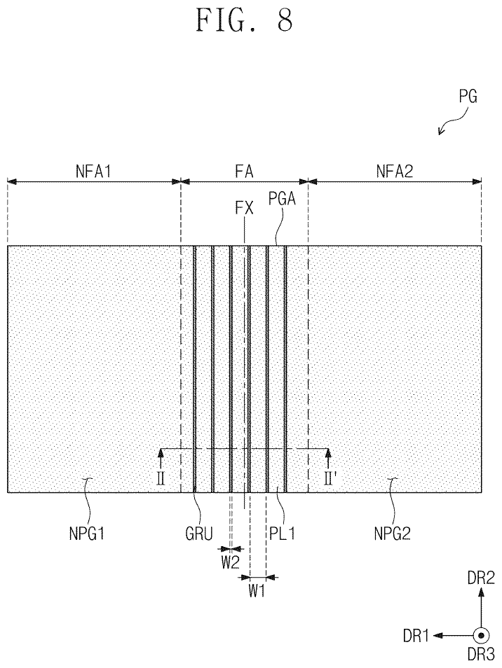

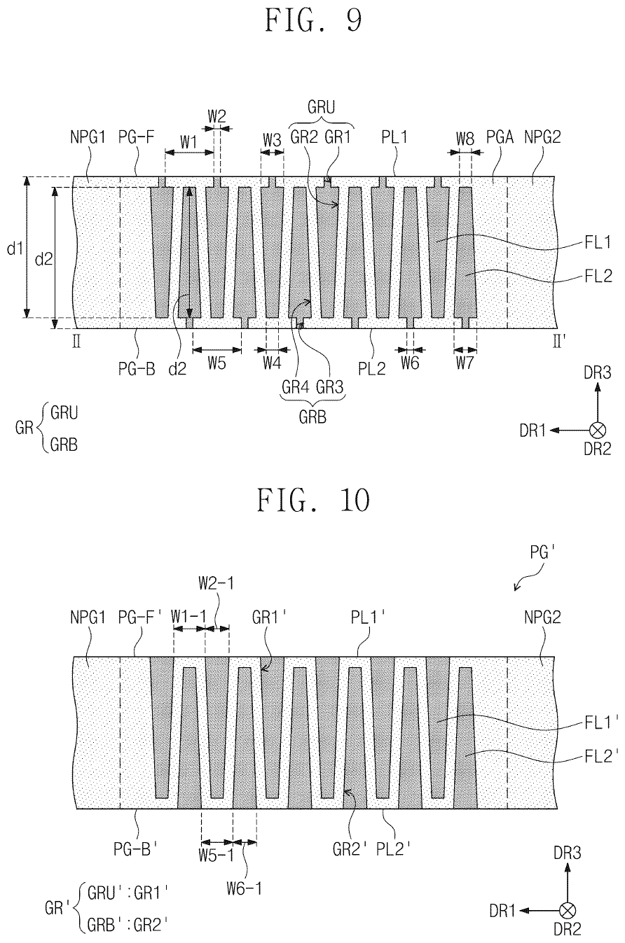

FIG. 7 is an enlarged view of a first region A1 in FIG. 4. FIG. 8 illustrates a patterned glass in FIG. 7. FIG. 9 is a cross-sectional view taken along line II-II′ in FIG. 8. FIG. 10 illustrates a comparative example of a patterned glass.

FIG. 7, FIG. 9, and FIG. 10 are cross-sectional views, and FIG. 8 is a plan view, for example.

Since first and second supporting plates SP1 and SP2, an anti-reflective layer RPL, a protective film PF, and a display module DM in FIG. 7 are the same as the first and second supporting plates SP1 and SP2, the anti-reflective layer RPL, the protective film PF, and the display module DM in FIG. 3 and FIG. 4, description thereof will be omitted or made briefly.

Referring to FIG. 7, FIG. 8, and FIG. 9, the window WM may include a patterned glass PG, a first window adhesive layer W_AL1, a second window adhesive layer W_AL2, a protective layer PLL, and filling resins FL1 and FL2.

The patterned glass PG may include a glass material. The patterned glass PG may include a patterned part PGA and first and second non-patterned part NPG1 and NPG2. The first non-patterned part NPG1, the patterned part PGA, and the second non-patterned part NPG2 may be arranged in a first direction DR1. The patterned part PGA may be disposed between the first and second non-patterned part NPG1 and NPG2. Substantially, the first non-patterned part NPG1, the patterned part PGA, and the second non-patterned part NPG2 may be formed as one piece.

The patterned part PGA may overlap the folding region FA. The first non-patterned part NPG1 may overlap the first non-folding region NFA1. The second non-patterned part NPG2 may overlap the second non-folding region NFA2.

The patterned glass PG may include an upper surface PG-F and a lower surface PG-B. In the patterned glass PG, the upper surface PG-F and the lower surface PG-B may refer to two surfaces opposed to each other in a third direction DR3. The lower surface PG-B of the patterned glass PG may be defined as a surface facing the anti-reflective layer RPL.

A plurality of patterns GR may be defined in the patterned part PGA. The patterns GR may include first patterns GRU and second patterns GRB. The first patterns GRU may be defined on the upper surface PG-F of the patterned glass PG. In a plan view, the first patterns GRU may extend in a second direction DR2 and may be arranged to be spaced apart from each other in the first direction DR1. The first patterns GRU may extend in the third direction DR3 from the upper surface PG-F toward the lower surface PG-B of the patterned glass PG. The first patterns GRU may extend by more than about half of the thickness of the patterned glass PG. The first patterns GRU may have depths greater than about half of the thickness of the patterned glass PG. Hereinafter, a depth d1 of each of the first patterns GRU may be defined as a first depth d1.

The first patterns GRU may include a plurality of first grooves GR1 and a plurality of second grooves GR2. In a plan view, the first grooves GR1 may extend in the second direction DR2 and may be defined to be spaced apart from each other in the first direction DR1. The first grooves GR1 may be defined to be closer to the upper surface PG-F of the patterned glass PG than the second grooves GR2 is to the upper surface PG-F of the patterned glass PG to be described later.

In a plan view, an upper surface of the patterned part PGA disposed between adjacent first patterns GRU may be defined as first surfaces PL1. A width of each of the first surfaces PL1 in the first direction DR1 may be defined as a first width W1. The first width W1 may be the same as a distance between adjacent first grooves GR1 in the first direction DR1. Here, an expression such as a first width between adjacent first grooves may mean a width between first grooves immediately next to each other among the plurality of first grooves.

The first grooves GR1 may extend in the third direction DR3. Widths of the first grooves GR1 in the first direction DR1 may be constant. A width of each of the first grooves GR1 in the first direction DR1 may be defined as a second width W2.

In a plan view, the second width W2 may be smaller than the first width W1. The second width W2 may be determined by the curvature radius R (refer to FIG. 2) of the electronic device ED (FIG. 2). A ratio of the second width W2 to the first width W1 may be determined by the curvature radius R (refer to FIG. 2) of the electronic device ED (FIG. 2).

The second grooves GR2 may be defined below the first grooves GR1. The second grooves GR2 may extend in the third direction DR3 from the first grooves GR1 toward the lower surface PG-B of the patterned glass PG. A width of each of the second grooves GR2 in the first direction DR1 may become smaller toward a lower surface PG-B of the patterned part PGA. In an embodiment, a third width W3 of an upper end of each of the second grooves GR2 adjacent to the first grooves GR1 may be greater than a fourth width W4 of a lower end of each of the second grooves GR2 adjacent to the lower surface PG-B of the patterned glass PG, for example.

The width of each of the second grooves GR2 in the first direction DR1 may be greater than the width of each of the first grooves GR1 in the first direction DR1. The third width W3 of the upper end of each of the second grooves GR2 and the fourth width W4 of the lower end of each of the second grooves GR2 may be greater than the second width W2 of each of the first grooves GR1.

Since the width of each of the second grooves GR2 in the first direction DR1 may be greater than the width of each of the first grooves GR1 in the first direction DR1, inner surfaces, of the patterned part PGA, defining the first grooves GR1 and the second grooves GR2 may have a step.

The second patterns GRB may be defined on the lower surface PG-B of the patterned glass PG. In a plan view, the second patterns GRB may be spaced apart from each other in the first direction DR1. Although not illustrated, in a plan view, each of the second patterns GRB may extend in the second direction DR2. The second patterns GRB may extend in the third direction DR3 from the lower surface PG-B toward the upper surface PG-F of the patterned glass PG. The second patterns GRB may extend by more than about half of the thickness of the patterned glass PG. The second patterns GRB may have depths greater than about half of the thickness of the patterned glass PG. Hereinafter, a depth d2 of each of the second patterns GRB may be defined as a second depth d2.

In an embodiment, the first patterns GRU and the second patterns GRB may have the same shape and may be symmetrical to each other in the third direction DR3. The first patterns GRU and the second patterns GRB may be alternately and inversely defined in the first direction DR1.

The second patterns GRB may include a plurality of third grooves GR3 and a plurality of fourth grooves GR4. Although not illustrated, in a plan view, the third grooves GR3 may extend in the second direction DR2. The third grooves GR3 may be defined to be spaced apart from each other in the first direction DR1. The third grooves GR3 may be defined to be closer to the lower surface PG-B of the patterned glass PG than the fourth grooves GR4 is to the lower surface PG-B of the patterned glass PG to be described later.

A lower surface of the patterned part PGA disposed between adjacent third grooves GR3 may be defined as second surfaces PL2. A width of each of the second surfaces PL2 in the first direction DR1 may be defined as a fifth width W5.

The third grooves GR3 may extend in the third direction DR3. Widths of the third grooves GR3 in the first direction DR1 may be constant. A width of each of the third grooves GR3 in the first direction DR1 may be defined as a sixth width W6.

In a plan view, the sixth width W6 may be smaller than the fifth width W5. The sixth width W6 may be determined by the curvature radius R (refer to FIG. 2) of the electronic device ED (FIG. 2). A ratio of the sixth width W6 to the fifth width W5 may be determined by the curvature radius R (refer to FIG. 2) of the electronic device ED (FIG. 2).

The first width W1 of each of the first surfaces PL1 and the fifth width W5 of each of the second surfaces PL2 may be the same. The second width W2 of each of the first grooves GR1 in the first direction DR1 and the sixth width W6 of each of the third grooves GR3 in the first direction DR1 may be the same.

The fourth grooves GR4 may be defined above the third grooves GR3. The fourth grooves GR4 may extend in the third direction DR3 from the third grooves GR3 toward the upper surface PG-F of the patterned glass PG. A width of each of the fourth grooves GR4 in the first direction DR1 may become smaller toward an upper surface PG-F of the patterned part PGA. In an embodiment, a seventh width W7 of a lower end of each of the fourth grooves GR4 adjacent to the third grooves GR3 may be greater than an eighth width W8 of an upper end of each of the fourth grooves GR4 adjacent to the upper surface PG-F of the patterned glass PG, for example.

In an embodiment, when viewed in the second direction DR2, shapes of the fourth grooves GR4 may be symmetrical to shapes of the second grooves GR2 in the third direction DR3. However, the shapes of the fourth grooves GR4 are not limited thereto.

The width of each of the fourth grooves GR4 in the first direction DR1 may be greater than the width of each of the third grooves GR3 in the first direction DR1. The seventh width W7 of the lower end and the eighth width W8 of the upper end of each of the fourth grooves GR4 may be greater than the sixth width W6 of each of the third grooves GR3.

Since the width of each of the fourth grooves GR4 in the first direction DR1 may be greater than the width of each of the third grooves GR3 in the first direction DR1, inner surfaces, of the patterned part PGA, defining the third grooves GR3 and the fourth grooves GR4 may have a step.

In an embodiment, when viewed in the second direction DR2, the first grooves GR1 and the third grooves GR3 may be symmetrical to each other in the third direction DR3. The second grooves GR2 and the fourth grooves GR4 may be symmetrical to each other in the third direction DR3. The second width W2 of each of the first grooves GR1 may be the same as the sixth width W6 of each of the third grooves GR3. The third width W3 and the fourth width W4 of each of the second grooves GR2 may be respectively the same as the seventh width W7 and the eighth width W8 of each of the fourth grooves GR4.

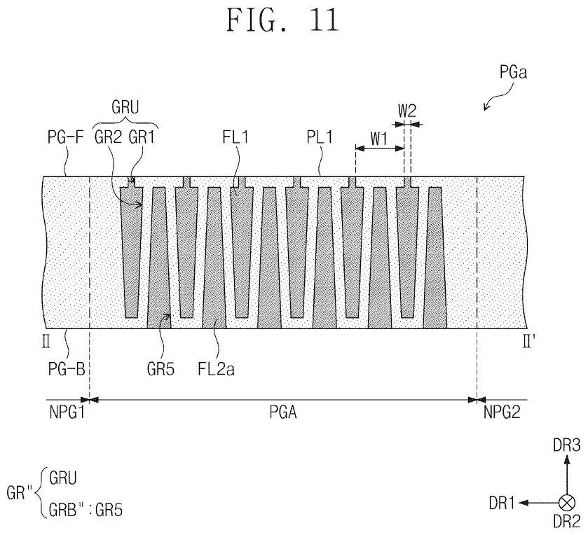

However, this is an illustrative embodiment, and thus the first patterns GRU and the second patterns GRB may have different shapes. This will be described in detail with reference to FIG. 11.

When viewed in the second direction DR2, the first grooves GR1 and the third grooves GR3 may be alternately and inversely disposed. When viewed in the second direction DR2, the second grooves GR2 and the fourth grooves GR4 may be alternately and inversely disposed.

The filling resins FL1 and FL2 may include first filling resins FL1 and second filling resins FL2. The first filling resins FL1 may be disposed in the first patterns GRU. The second filling resins FL2 may be disposed in the second patterns GRB.

The first filling resins FL1 may have shapes corresponding to those of the first grooves GR1 and the second grooves GR2. The second filling resins FL2 may have shapes corresponding to those of the third grooves GR3 and the fourth grooves GR4.

Accordingly, a width of each of the first filling resins FL1 adjacent to the upper surface PG-F of the patterned glass PG may be the same as the second width W2. A width of each of the second filling resins FL2 adjacent to the lower surface PG-B of the patterned glass PG may be the same as the sixth width W6.

The first width W1 of each of the first surfaces PL1 in the first direction DR1 may be greater than a second width W2 of each of the first filling resins FL1. The fifth width W5 of each of the second surfaces PL2 may be greater than a sixth width W6 of each of the second filling resins FL2.

Referring to FIG. 10, first grooves GR1′ of first patterns GRU′ of a plurality of patterns GR′ may be defined in an upper surface PG-F′ of a patterned glass PG′ in a comparative example. The first grooves GR1′ may be defined to be spaced apart from each other in a first direction DR1. An upper surface of the patterned glass PG′ disposed between adjacent first grooves GR1′ in the first direction DR1 may be defined as a first surface PL1′. A width of the first surface PL1′ in the first direction DR1 may be defined as a (1-1)-th width W1-1. When viewed in a second direction DR2, a width of each of the first grooves GR1′ in the first direction DR1 may be defined as a (2-1)-th width W2-1.

The first grooves GR1′ may extend in a third direction DR3 from the upper surface PG-F′ of the patterned glass PG′ toward a lower surface PG-B′ of the patterned glass PG′. First filling resins FL1′ may be disposed in the first grooves GR1′. The first filling resins FL1′ may have shapes corresponding to those of the first grooves GR1′. Accordingly, a width of each of the first filling resins FL1′ adjacent to the upper surface PG-F′ of the patterned glass PG′ may be the same as the (2-1)-th width W2-1.

Second grooves GR2′ of second patterns GRB′ of the plurality of patterns GR′ may be defined in the lower surface PG-B′ of the patterned glass PG′. The second grooves GR2′ may be defined to be spaced apart from each other in the first direction DR1. A lower surface PG-B′ of the patterned glass PG′ disposed between adjacent second grooves GR2′ in the first direction DR1 may be defined as a second surface PL2′. A width of the second surface PL2′ in the first direction DR1 may be defined as a (5-1)-th width W5-1. When viewed in the second direction DR2, a width of each of the second grooves GR2′ in the first direction DR1 may be defined as a (6-1)-th width W6-1.

The second grooves GR2′ may extend in the third direction DR3 from the lower surface PG-B′ of the patterned glass PG′ toward the upper surface PG-F′ of the patterned glass PG′. Second filling resins FL2′ may be disposed in the second grooves GR2′. The second filling resins FL2′ may have shapes corresponding to those of the second grooves GR2′. Accordingly, a width of each of the second filling resins FL2′ adjacent to the lower surface PG-B′ of the patterned glass PG′ may be the same as the (6-1)-th width W6-1.

Referring to FIG. 9 and FIG. 10, the upper surfaces PG-F and PG-F′ of the patterned glasses PG and PG′ may each be a front surface of the display device DD (refer to FIG. 3). As areas of first fillers FL1 and FL1′ exposed to the outside from the upper surfaces PG-F and PG-F′ increase in areas of the upper surfaces PG-F and PG-F′ of the patterned glasses PG and PG′, the first grooves GR1 and GR1′ may be visible to a user.

In an embodiment, the ratio of the (2-1)-th width W2-1 to the (1-1)-th width W1-1 may be greater than the ratio of the second width W2 to the first width W1. That is, the value of the (2-1)-th width W2-1 divided by the (1-1)-th width W1-1 may be greater than the value of the second width W2 divided by the first width W1. The (2-1)-th width W2-1 may be greater than the second width W2.

The ratio of the (6-1)-th width W6-1 to the (5-1)-th width W5-1 may be greater than the ratio of the sixth width W6 to the fifth width W5. That is, the value of the (6-1)-th width W6-1 divided by the (5-1)-th width W5-1 may be greater than the value of the sixth width W6 divided by the fifth width W5. The (6-1)-th width W6-1 may be greater than the sixth width W6.

Accordingly, the second width W2 of each of the first grooves GR1 in FIG. 9 may be smaller than the (2-1)-th width W2-1 of each of the first grooves GR1′ in FIG. 10, and the sixth width W6 of each of the third grooves GR3 in FIG. 9 may be smaller than the (6-1)-th width W6-1 of each of the second grooves GR2′ in FIG. 10. Thus, the first patterns GRU and the second patterns GRB on the patterned glass PG in FIG. 9 may be less likely to be visible to a user.

Referring to FIG. 10, light may be emitted from the display panel DP (refer to FIG. 3) toward the display surface DS (refer to FIG. 1). The light may pass through the patterned glass PG′. A refractive index of the patterned glass PG′ and a refractive index of the second filling resins FL2′ may be different. Accordingly, a path of light incident from second surfaces PL2′ and a path of light incident onto the second filling resins FL2′ may be different. Thus, the second filling resins FL2′ may be visible to a user.

Referring to FIG. 9 and FIG. 10, a sixth width W6 of each of the second filling resins FL2 may be smaller than the (6-1)-th width W6-1. The ratio of the sixth width W6 to the fifth width W5 may be smaller than the ratio of the (6-1)-th width W6-1 to the (5-1)-th width W5-1. That is, the value of the sixth width W6 divided by the fifth width W5 may be smaller than the value of the (6-1)-th width W6-1 divided by the (5-1)-th width W5-1. Accordingly, even when a path of light incident onto the second surfaces PL2 and a path of light incident onto the second filling resins FL2 are different from each other, the second filling resins FL2 may not be visible to a user.

Referring to FIG. 7, the protective layer PLL may include a first protective layer PLL1 and a second protective layer PLL2. The first protective layer PLL1 may be disposed below the patterned glass PG. The second protective layer PLL2 may be disposed on the patterned glass PG.

The protective layer PLL may serve as protecting the patterned glass PG from an external impact. The protective layer PLL may include a synthetic resin material. In an embodiment of the inventive concept, the protective layer PLL may include at least one selected from among a urethane-based resin, an epoxy-based resin, a polyester-based resin, a polyether-based resin, an acrylate-based resin, an acrylonitrile-butadiene-styrene (“ABS”) resin, and rubber. More specifically, the protective layer PLL may include at least one of phenylene, polyethylene terephthalate (“PET”), polyimide (“PI”), polyamide (“PAI”), polyethylene naphthalate (“PEN”), or polycarbonate (“PC”).

The first window adhesive layer W_AL1 may be disposed on a lower surface of the patterned glass PG. The first window adhesive layer W_AL1 may be disposed between the patterned glass PG and the first protective layer PLL1. The first window adhesive layer W_AL1 may be disposed between the patterned glass PG and the first protective layer PLL1 to attach the first protective layer PLL1 onto the lower surface of the patterned glass PG.

The second window adhesive layer W_AL2 may be disposed on an upper surface of the patterned glass PG. The second window adhesive layer W_AL2 may be disposed between the patterned glass PG and the second protective layer PLL2. The second window adhesive layer W_AL2 may be disposed between the patterned glass PG and the second protective layer PLL2 to attach the second protective layer PLL2 onto the upper surface of the patterned glass PG.

The first window adhesive layer W_AL1 and the second window adhesive layer W_AL2 may include an optically transparent adhesive material. The first window adhesive layer W_AL1 and the second window adhesive layer W_AL2 may include a pressure sensitive adhesive (“PSA”), an optically clear adhesive (“OCA”), or an optically clear resin (“OCR”).

The display device DD (refer to FIG. 3) may further include first to third adhesive layers AF1 to AF3. The first adhesive layer AF1 may be disposed between the anti-reflective layer RPL and the display module DM. The anti-reflective layer RPL and the display module DM may be bonded to each other through the first adhesive layer AF1.

The second adhesive layer AF2 may be disposed between the display module DM and the protective film PF. The display module DM and the protective film PF may be bonded to each other through the second adhesive layer AF2.

The third adhesive layer AF3 may be disposed between the protective film PF and the supporting plates SP1 and SP2. The third adhesive layer AF3 may include a (3_1)-th adhesive layer AF3_1 and a (3_2)-th adhesive layer AF3_2. The (3_1)-th adhesive layer AF3_1 and the (3_2)-th adhesive layer AF3_2 may be spaced apart from each other in the first direction DR1. The (3_1)-th adhesive layer AF3_1 and the (3_2)-th adhesive layer AF3_2 may be disposed to respectively correspond to the first and second non-folding regions NFA1 and NFA2. The (3_1)-th adhesive layer AF3_1 may be disposed to overlap the first non-folding region NFA1, and the (3_2)-th adhesive layer AF3_2 may be disposed to overlap the second non-folding region NFA2.

FIG. 11 is a drawing for describing an embodiment of a patterned glass.

In an embodiment, FIG. 11 is a cross-sectional view taken along line II-II′ in FIG. 8.

Since first patterns GRU and first filling resins FL1 in FIG. 11 are the same as the first patterns GRU and first filling resins FL1 in FIG. 9, description thereof will be omitted or made briefly.

Referring to FIG. 11, fifth grooves GR5 of second patterns GRB″ of the plurality of patterns GR″ may be defined in a lower surface PG-B of a patterned glass PGa. The fifth grooves GR5 may be defined to be spaced apart from each other in a first direction DR1. Although not illustrated, the fifth grooves GR5 may extend in a second direction DR2.

The fifth grooves GR5 may extend in a third direction DR3 from the lower surface PG-B toward an upper surface PG-F of the patterned glass PGa. The fifth grooves GR5 may extend by more than about half of the thickness of the patterned glass PGa. The fifth grooves GR5 may have depths greater than about half of the thickness of the patterned glass PGa.

When viewed in the second direction DR2, the fifth grooves GR5 and second grooves GR2 may be alternately and inversely disposed.

Second filling resins FL2a may be disposed in the fifth grooves GR5. The second filling resins FL2a may have shapes corresponding to those of the fifth grooves GR5. When viewed in the second direction DR2, the second filling resins FL2a and first filling resins FL1 may be alternately and inversely disposed.

The upper surface PG-F of the patterned glass PGa may be a front surface of the display device DD (refer to FIG. 3). Since a second width W2 of each of first grooves GR1 defined in an upper surface of the patterned glass PGa may decrease, first patterns GRU may be prevented from being viewed to a user.

In an embodiment, shapes of the fifth grooves GR5 are defined in the lower surface PG-B of the patterned glass PGa, but the inventive concept is not limited thereto. Thus, depending on a folding direction of the electronic device ED (refer to FIG. 1), the fifth grooves GR5 may be defined in the upper surface PG-F of the patterned glass PGa, and the first grooves GR1 and the second grooves GR2 may be defined in the lower surface PG-B of the patterned glass PGa.

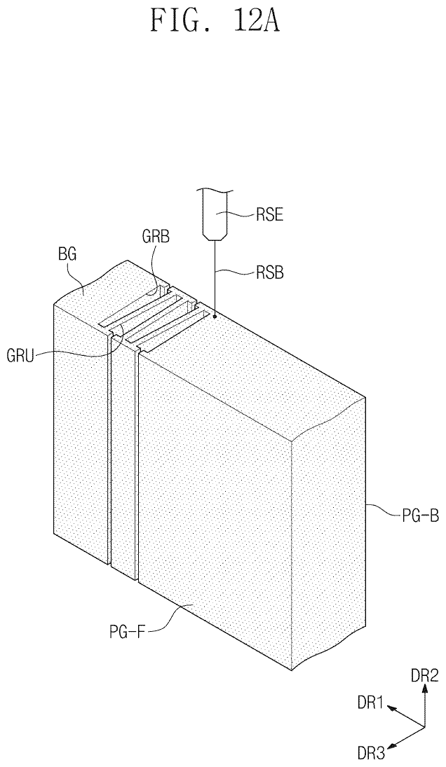

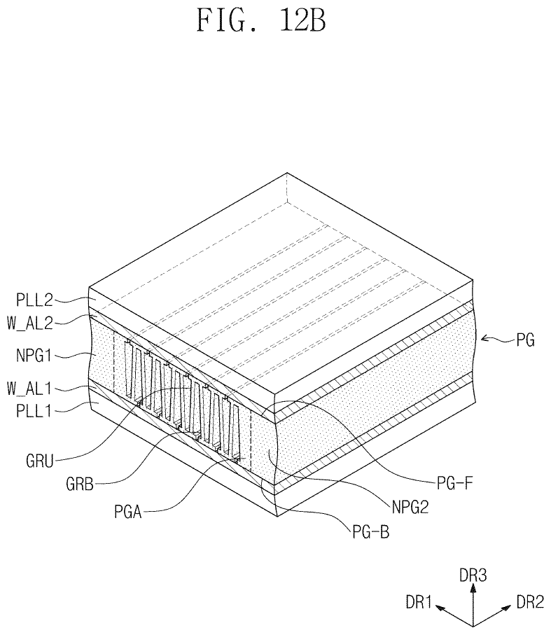

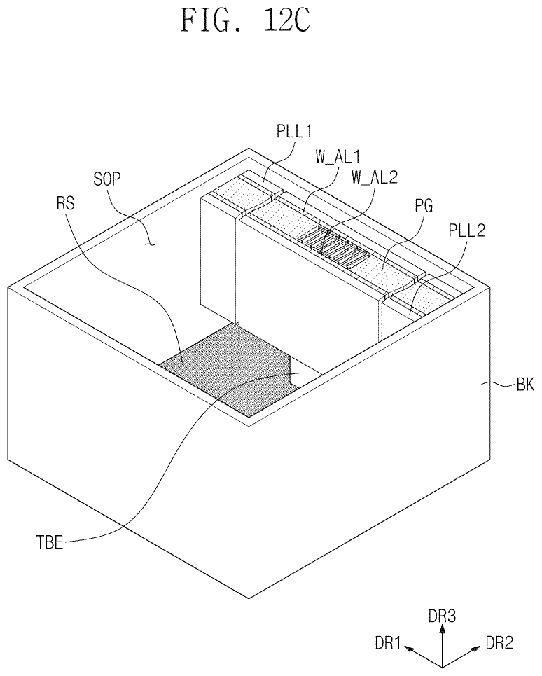

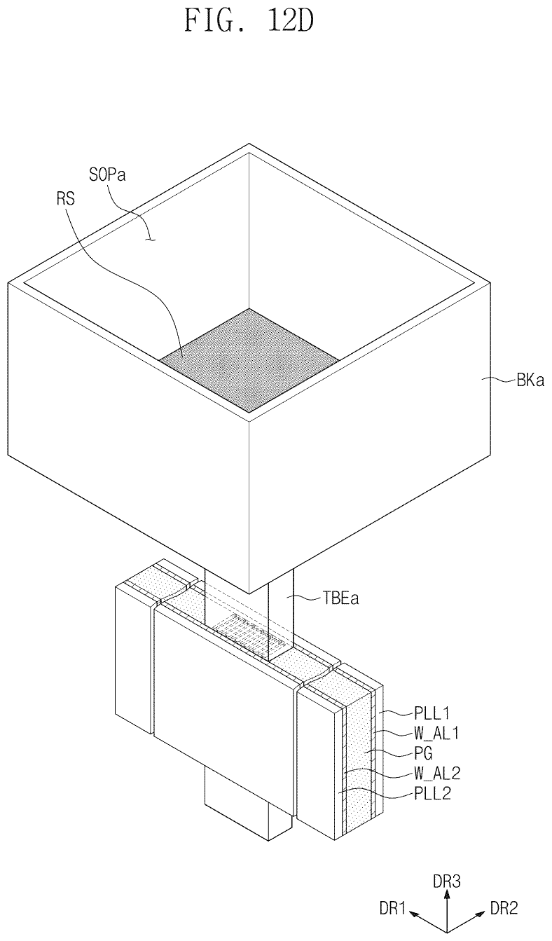

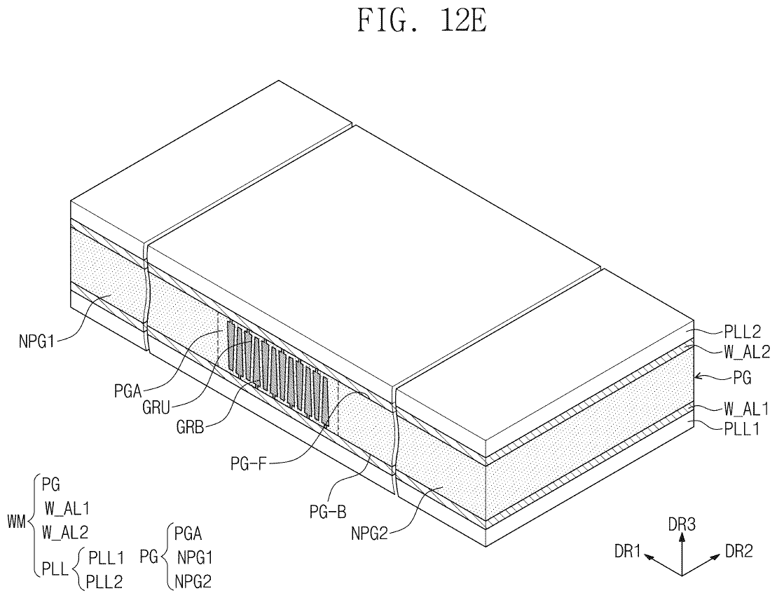

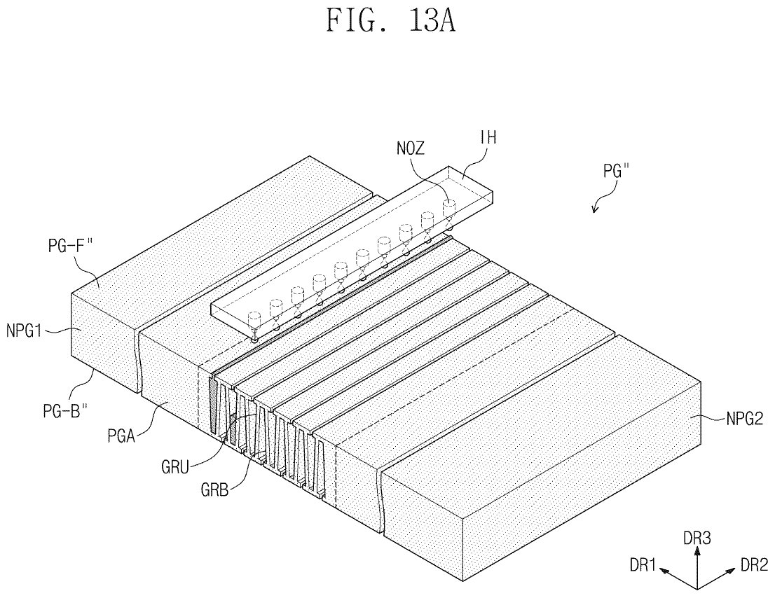

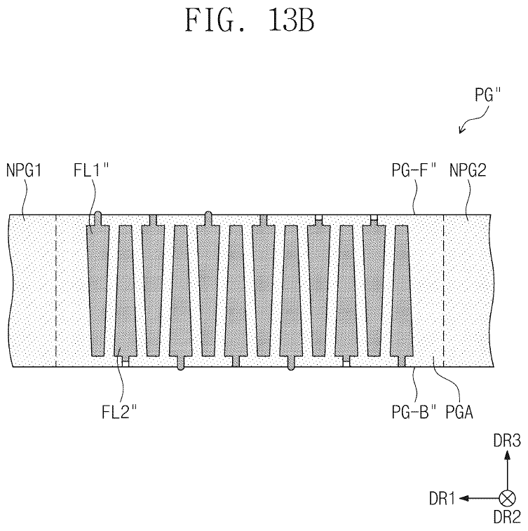

FIGS. 12A to 12E are drawings for describing a method for manufacturing a window illustrated in FIG. 7. FIG. 13A and FIG. 13B illustrate a comparative example of a patterned glass.

In an embodiment, FIGS. 12A to 13A are perspective views, and FIG. 13B is a cross-sectional view.

Since first patterns GRU, second patterns GRB, a protective layer PLL, and first and second window adhesive layers W_AL1 and W_AL2 in FIGS. 12A to 12E are the same as the first patterns GRU, the second patterns GRB, the protective layer PLL, and the first and second window adhesive layers W_AL1 and W_AL2 in FIGS. 7 to 9, description thereof will be omitted or made briefly.

Referring to FIG. 12A, a method for manufacturing a window may include forming first patterns GRU and second patterns GRB. A light irradiation unit RSE may be disposed above a glass BG. The light irradiation unit RSE may emit an intense light (e.g., laser beam RSB) on the glass BG. One surface of the glass BG may be irradiated with the laser beam (e.g., a ultrashort pulse laser beam) RSB. The first patterns GRU and the second patterns GRB may be defined on the glass BG by the laser beam RSB. Each of the first patterns GRU and the second patterns GRB may extend in a second direction DR2 and may be arranged in a first direction DR1. The first patterns GRU and the second patterns GRB may extend in the second direction DR2 and may be defined on two sides, of a patterned glass PG, opposed to each other in the second direction DR2.

Referring to FIG. 12B, after the first patterns GRU and the second patterns GRB are defined, sealing the first patterns GRU and the second patterns GRB may be performed. A first window adhesive layer W_AL1 may be disposed on a lower surface PG-B of a patterned glass PG. The first window adhesive layer W_AL1 may cover the second patterns GRB defined on the lower surface PG-B of the patterned glass PG.

A first protective layer PLL1 may be disposed on a lower surface of the first window adhesive layer W_AL1. The first window adhesive layer W_AL1 may be disposed between the first protective layer PLL1 and the patterned glass PG. The first protective layer PLL1 and the patterned glass PG may be bonded to each other through the first window adhesive layer W_AL1.

A second window adhesive layer W_AL2 may be disposed on an upper surface PG-F of the patterned glass PG. The second window adhesive layer W_AL2 may cover the first patterns GRU defined on the upper surface PG-F of the patterned glass PG.

A second protective layer PLL2 may be disposed on an upper surface of the second window adhesive layer W_AL2. The second window adhesive layer W_AL2 may be disposed between the second protective layer PLL2 and the patterned glass PG. The second protective layer PLL2 and the patterned glass PG may be bonded to each other through the second window adhesive layer W_AL2.

The first patterns GRU adjacent to the upper surface PG-F of the patterned glass PG and the second patterns GRB adjacent to the lower surface PG-B of the patterned glass PG may be sealed with the second window adhesive layer W_AL2 and the first window adhesive layer W_AL1.

Referring to FIG. 12C and FIG. 12E, after the first patterns GRU and the second patterns GRB are sealed, filling the first patterns GRU and the second patterns GRB with a resin may be performed.

Filling the first patterns GRU and the second patterns GRB with a resin RS may include preparing a water tank BK. An accommodation groove SOP may be defined in an upper surface of the water tank BK. The accommodation groove SOP may extend from the upper surface to a lower surface of the water tank BK.

After the preparing of the water tank BK, providing the resin RS into the accommodation groove SOP may be performed. Then, a tube TBE may be connected to the patterned glass PG. The tube TBE may have one side and an opposite side opposed to each other in a third direction DR3, the one side being connected to the patterned glass PG and an opposite side being disposed on the resin RS.

The resin RS may move toward the first patterns GRU and the second patterns GRB through capillarity. Specifically, adhesion strength between the resin RS and an inner surface of the tube TBE may be greater than cohesion strength between molecules of the resin RS. Accordingly, the resin RS may ascend along the inner surface of the tube TBE.

After provided to the patterned glass PG through the tube TBE, the resin RS may be filled into the first patterns GRU and the second patterns GRB. Adhesion between the resin RS and the patterned glass PG may be greater than cohesion between molecules of the resin RS. Accordingly, the resin RS may ascend along an inner surface of the patterned glass PG defining the first patterns GRU and the second patterns GRB.

Although not illustrated, after the first patterns GRU and the second patterns GRB are filled with the resin RS, the resin RS may be cured. In an embodiment, the resin RS may be cured through thermal curing or ultraviolet curing. When the resin RS is cured, first filling resins FL1 and second filling resins FL2 may be obtained.

Referring to FIG. 13A and FIG. 13B, the resin RS may be filled into first patterns GRU and second patterns GRB through an inkjet method. Specifically, an inkjet head IH and nozzles NOZ may be disposed above a patterned glass PG″. The nozzles NOZ may be disposed on a lower surface of the inkjet head IH. The nozzles NOZ may be arranged in a second direction DR2.

The nozzles NOZ may discharge the resin RS. The nozzles NOZ may discharge the resin RS toward the first patterns GRU. Although not illustrated, after the resin RS is filled into the first patterns GRU, the nozzles NOZ may discharge the resin RS to the second patterns GRB as well.

When the nozzles NOZ discharge the resin RS toward the first patterns GRU and the second patterns GRB, the amounts of the resin RS discharged to the respective first patterns GRU may be different from each other due to errors in a process, etc. The amounts of the resin RS discharged to the respective second patterns GRB may be different from each other. As illustrated in FIG. 13B, heights of upper surfaces of first filling resins FL1″ which are filled into adjacent first patterns GRU may be different from each other. Heights of upper surfaces of second filling resins FL2″ which are filled into adjacent second patterns GRB may be different from each other. Accordingly, an upper surface PG-F″ and a lower surface PG-B″ of the patterned glass PG″ may become uneven, and the protective layer PLL (refer to FIG. 7) and the window adhesive layers W_AL1 and W_AL2 (refer to FIG. 7) disposed on an upper surface and a lower surface of the patterned glass PG″ may be uneven. Therefore, the surface quality of the electronic device ED (refer to FIG. 1) may be deteriorated.

Referring to FIG. 7 and FIG. 12C, since the resin RS may be filled into the first patterns GRU and the second patterns GRB through capillarity, heights of upper surfaces of the first filling resins FL1 may be the same. Heights of upper surfaces of the second filling resins FL2 may be the same. Accordingly, the upper surface PG-F and the lower surface PG-B of the patterned glass PG may be even. The protective layer PLL (refer to FIG. 7) and the window adhesive layers W_AL1 and W_AL2 (refer to FIG. 7) disposed on the upper surface PG-F and the lower surface PG-B of the patterned glass PG may be even. Therefore, the surface quality of the electronic device ED (refer to FIG. 1) may be improved.

Referring to FIG. 12C, one patterned glass PG in the water tank BK is illustrated in an embodiment, but the inventive concept is not limited thereto, and thus a plurality of patterned glasses PG may be simultaneously disposed in the accommodation groove SOP. That is, the resin RS may be simultaneously filled into the first patterns GRU and the second patterns GRB on the patterned glasses PG. Thus, mass productivity of windows WM including the patterned glasses PG may be improved.

Referring to FIG. 12D, a water tank BKa may be disposed above the patterned glass PG. The patterned glass PG and the water tank BKa may be connected to each other through a tube TBEa. Although not illustrated, an opening may be defined in a lower surface of the water tank BKa so that the resin RS may move toward the tube TBEa.

The resin RS accommodated in an accommodation groove SOPa may move toward the first patterns GRU and the second patterns GRB through the tube TBEa. Specifically, the resin RS may move along an inner surface of the tube TBEa through gravity and capillarity. The resin RS may be provided to the patterned glass PG through the tube TBEa, and then the resin RS may be filled into the first patterns GRU and the second patterns GRB. The resin RS may be filled into the first patterns GRU and the second patterns GRB through capillarity and gravity.

In an embodiment of the inventive concept, a resin may be simultaneously filled into grooves in a patterned glass through capillarity. Thus, resins may be uniformly filled into patterns, thereby improving mass productivity.

In an embodiment of the inventive concept, patterns may include a first groove defined in an upper surface of a window, a second groove extending from the first groove toward a lower surface of the window, a third groove defined in the lower surface of the window, and a fourth groove extending from the third groove toward the upper surface of the window. A width of the first groove may be smaller than a width of the second groove. A width of the third groove may be smaller than a width of the fourth groove. Since the first groove and the third groove having relatively small widths may be respectively defined in the upper surface and the lower surface of the window, patterns may be invisible to a user, and therefore, a display device may have improved surface quality.

Although description has been made with reference to the embodiments of the inventive concept, it is understood that the inventive concept should not be limited to these embodiments, but various changes and modifications may be made by a person skill in the art within the spirit and scope of the inventive concept as hereinafter claimed. In addition, embodiments disclosed in the inventive concept are not intended to limit the technical spirit of the inventive concept, and all technical ideas within the scope of the following claims and their equivalents should be construed as being included in the scope of the inventive concept.

What is claimed is:

1. A display device comprising:
a display panel; and
a patterned glass disposed on the display panel and including a first non-patterned part, a patterned part, and a second non-patterned part, which are arranged in a first direction,
wherein a first groove extending in a second direction crossing the first direction in a plan view, and a second groove extending from the first groove toward a lower surface of the patterned part are defined in an upper surface of the patterned part, and
a width of the first groove in the first direction is smaller than a width of the second groove.

2. The display device of claim 1, wherein the width of the second groove in the first direction becomes smaller toward the lower surface of the patterned part.

3. The display device of claim 1, wherein the first groove is defined in plural in the first direction in the upper surface of the patterned part,
the upper surface of the patterned part disposed between first grooves immediately next to each other among a plurality of first grooves is defined as a first surface, and
in the plan view, a width of each of the first grooves in the first direction is smaller than a width of the first surface in the first direction.

4. The display device of claim 1, wherein inner surfaces, of the patterned part, defining the first groove and the second groove have a step.

5. The display device of claim 1, wherein a third groove extending in the second direction and a fourth groove extending in a third direction from the third groove toward the upper surface of the patterned part are defined in the lower surface of the patterned part, the third direction crosses a plane defined by the first direction and the second direction, and a width of the third groove in the first direction is smaller than a width of the fourth groove.

6. The display device of claim 5, wherein, when viewed in the second direction, the second groove and the fourth groove are symmetrical to each other in the third direction, and the first groove and the third groove are symmetrical to each other in the third direction.

7. The display device of claim 6, wherein, when viewed in the second direction, the second groove and the fourth groove are alternately and inversely disposed in the first direction.

8. The display device of claim 5, wherein the width of the fourth groove in the first direction becomes smaller toward the upper surface of the patterned part.

9. The display device of claim 5, wherein the third groove is defined in plural in the first direction in the lower surface of the patterned part,
the lower surface of the patterned part disposed between third grooves immediately next to each other among a plurality of third grooves is defined as a second surface, and
in the plan view, a width of each of the third grooves in the first direction is smaller than a width of the second surface in the first direction.

10. The display device of claim 5, wherein inner surfaces, of the patterned part, defining the third groove and the fourth groove have a step.

11. The display device of claim 1, wherein a fifth groove extending from the lower surface of the patterned part toward the upper surface of the patterned part is defined in the lower surface of the patterned part, and
a width of the fifth groove in the first direction becomes smaller toward the upper surface of the patterned part.

12. A window manufacturing method comprising:
forming, on an upper surface of a glass, a plurality of patterns arranged in a first direction and extending in a second direction crossing the first direction by irradiating the glass with a laser beam;
sealing the plurality of patterns; and
filling the plurality of patterns with a resin,
wherein the resin is filled in the plurality of patterns through capillarity.

13. The window manufacturing method of claim 12, wherein the plurality of patterns comprises:
a first groove defined in the upper surface of the glass and extending in the second direction in a plan view; and
a second groove extending from the first groove toward a lower surface of the glass.

14. The window manufacturing method of claim 13, wherein a width of the second groove in the first direction is greater than a width of the first groove in the first direction.

15. The window manufacturing method of claim 13, wherein the plurality of patterns further comprises:
a third groove defined in the lower surface of the glass and extending in the second direction in the plan view; and
a fourth groove extending from the third groove toward the upper surface of the glass.

16. The window manufacturing method of claim 15, wherein a width of the fourth groove in the first direction is greater than a width of the third groove in the first direction.

17. The window manufacturing method of claim 15, wherein, when viewed in the second direction, the first groove is symmetrical to the third groove in a third direction crossing a plane defined by the first direction and the second direction, and the second groove and the fourth groove are symmetrical to each other in the third direction.

18. The window manufacturing method of claim 17, wherein when viewed in the second direction, the second groove and the fourth groove are alternately and inversely disposed in the first direction.

19. The window manufacturing method of claim 12, wherein the sealing of the plurality of patterns comprises:
disposing a plurality of protective layers on the upper surface and a lower surface of the glass; and
disposing a plurality of adhesive layers between the glass and the plurality of protective layers, and
the plurality of adhesive layers covers the plurality of patterns on the glass.

20. The window manufacturing method of claim 15, comprising:
preparing a water tank having an accommodation groove defined therein;
providing a resin into the accommodation groove;
connecting a tube to the plurality of patterns; and
disposing the glass in the accommodation groove,
wherein the resin moves toward the plurality of patterns along the tube.
